(19) United States
(12) Patent Application Publication
(10) Pub. No.: US 2025/0077348 A1
(43) Pub. Date: Mar. 6, 2025

(54) POST PACKAGE REPAIR RESOURCES FOR MEMORY DEVICES

(71) Applicant: Micron Technology, Inc., Boise, ID (US)

(72) Inventors: Antonino Capri', Bergamo (IT); Daniele Balluchi, Cernusco Sul Naviglio MI (IT); Joseph M. McCrate, Boise, ID (US); Graziano Mirichigni, Vimercate (IT); Danilo Caraccio, Milano (IT); Marco Sforzin, Cernusco Sul Naviglio MI (IT)

(21) Appl. No.: 18/776,730

(22) Filed: Jul. 18, 2024

Related U.S. Application Data
(60) Provisional application No. 63/536,871, filed on Sep. 6, 2023.

(51) Int. Cl. G06F 11/10

(52) U.S. Cl. CPC G06F 11/1064

(57) ABSTRACT

A variety of applications can include a memory device implementing one or more caches or buffers integrated with a controller of the memory device to provide post package repair resources. The one or more caches or buffers can be separate from the media subsystem that stores user data for the memory device. Arrangements of the one or more caches or buffers can include the one or more caches or buffers structured between decoder-encoder arrangements of the memory device and the media subsystem of the memory device. Other arrangements of the one or more caches or buffers can include decoder-encoder arrangements of the memory device structured between the one or more caches or buffers and the media subsystem of the memory device. Combinations of arrangements may be implemented. Additional apparatus, systems, and methods are disclosed.

### PRIORITY APPLICATION

This application claims the benefit of priority to U.S. Provisional Application Ser. No. 63/536,871, filed Sep. 6, 2023, which is incorporated herein by reference in its entirety.

### FIELD OF THE DISCLOSURE

Embodiments of the disclosure relate generally to electronic devices and, more specifically, to storage memory devices and operation thereof.

### BACKGROUND

Memory devices are typically provided as internal, semiconductor, integrated circuits in computers or other electronic devices in a variety of manufactured products. There are many different types of memory, including volatile and non-volatile memory. Volatile memory requires power to maintain its data, and examples of volatile memory include random-access memory (RAM), dynamic random-access memory (DRAM), static RAM (SRAM), and synchronous dynamic random-access memory (SDRAM), among others. Non-volatile memory can retain stored data when not powered, and examples of non-volatile memory include flash memory, read-only memory (ROM), electrically erasable programmable ROM (EEPROM), erasable programmable ROM (EPROM), resistance variable memory, such as phase-change random-access memory (PCRAM), resistive random-access memory (RRAM), magnetoresistive random-access memory (MRAM), and three-dimensional (3D) XPoint™ memory, among others.

The various types of memories can be used in applications in which manufacturers of consumer products use architectures for memory devices, which architectures can include one or more memory subsystems having multiple individual storage memory media in which the memory device interacts with a host device to store user data in the one or more memory subsystems of the memory device. The host device and the memory devices can operate using one or more protocols that can include standardized protocols. Operation and properties of memory devices and other electronic devices in systems can be improved by enhancements to the procedures and design of these electronic devices for their introduction into the systems for which the electronic devices are intended.

### BRIEF DESCRIPTION OF THE DRAWINGS

The drawings, which are not necessarily drawn to scale, illustrate generally, by way of example, but not by way of limitation, various embodiments discussed in the present document.

FIG. 1 illustrates an example of an application of a fourth generation of double data rate random-access memory registered dual in-line memory module, according to various embodiments.

FIG. 2 illustrates an example of a virtual row and a physical row for a memory medium with respect to a command from a host, according to various embodiments.

FIG. 3 illustrates an example of a virtual row and a physical row of an example fourth generation of double data rate random-access memory registered dual in-line memory module, according to various embodiments.

FIG. 4 illustrates an example of a buffer/cache arrangement in a controller to provide post package repair resources in a virtual repair situation for multiple modules of memory media, in which the buffer/cache arrangement is in a shared configuration, according to various embodiments.

FIG. 5 illustrates an example of a buffer/cache arrangement in a controller to provide post package repair resources in a virtual repair situation for multiple modules of memory media, in which the buffer/cache arrangement is in a non-shared configuration, according to various embodiments.

FIG. 6 illustrates an example of a buffer/cache arrangement in a controller to provide post package repair resources in a physical repair situation for multiple modules of memory media, in which the buffer/cache arrangement is in a shared configuration, according to various embodiments.

FIG. 7 illustrates an example of a buffer/cache arrangement in a controller to provide post package repair resources in a physical repair situation for multiple modules of memory media, in which the buffer/cache arrangement is in a non-shared configuration, according to various embodiments.

FIG. 8 shows a table illustrating example options available that are associated with post package repair buffer/cache data size for an example dual rank configuration, according to various embodiments.

FIG. 9 illustrates an example of a buffer/cache arrangement for a memory media configuration having modules of memory media coupled to a controller, according to various embodiments.

FIG. 10 illustrates an example of a buffer/cache in a non-shared arrangement for a memory media configuration having modules of memory media coupled to a controller with single channels, according to various embodiments.

FIG. 11 illustrates an example of a buffer/cache arrangement for a memory media configuration having modules of memory media coupled to a controller with four channels, according to various embodiments.

FIG. 12 illustrates an example of a single channel between a module of memory media and a controller, according to various embodiments.

FIG. 13 illustrates an example of direct map per rank upon reception of an address from a host, according to various embodiments.

FIG. 14 illustrates an example of a two-way set associative mapping per rank upon reception of an address from a host, according to various embodiments.

FIG. 15 illustrates an example of a fully associative mapping per rank upon reception of an address from a host, according to various embodiments.

FIG. 16 is a flow diagram of an example of filling a buffer/cache of a post package repair resource in a background mode of operation of a memory device, according to various embodiments.

FIG. 17 is a flow diagram of an example of filling a buffer/cache of a post package repair resource in a foreground mode of operation of a memory device, according to various embodiments.

FIG. 18 illustrates an example of direct map per rank in a foreground mode operation of FIG. 17 upon reception of an address from a host in the example structure of FIG. 12 and the table of FIG. 8, according to various embodiments.

FIG. 19 illustrates an example a memory device implemented with a two-channel fourth generation of double data rate random-access memory dual in-line memory module in which a buffer/cache for post package repair is integrated in a controller of the memory device, according to various embodiments.

FIG. 20 is a flow diagram of features of an example method of operating a memory device, according to various embodiments.

FIG. 21 is a flow diagram of features of another example method of operating a memory device, according to various embodiments.

FIG. 22 illustrates a block diagram of example component features of a compute express link system that includes a buffer/cache for post package repair integrated in a controller of a memory device, according to various embodiments.

FIG. 23 is a block diagram of an example system including a host that operates with a memory device having one or more memory media, where the memory device can implement post package repair in a buffer/cache in a processing device of the memory device, according to various embodiments.

### DETAILED DESCRIPTION

The following detailed description refers to the accompanying drawings that show, by way of illustration and not limitation, various embodiments in which an invention can be practiced. These embodiments are described in sufficient detail to enable those skilled in the art to practice these and other embodiments. Other embodiments may be utilized, and structural, logical, mechanical, and electrical changes may be made to these embodiments. The various embodiments are not necessarily mutually exclusive, as some embodiments can be combined with one or more other embodiments to form new embodiments. The following detailed description is, therefore, not to be taken in a limiting sense.

Post package repair (PPR) resources are used to repair rows during the manufacturing phase of memory devices before shipping the products to the customer or during the usage of the products from the final user until PPRs are available. Execution of standard PPR flow typically uses dedicated component commands, without user activity, and is significantly time consuming. In an example, double data rate (DDR) memory components have a limited number of PPR resources. Such resources typically are one row per bank group or one row per bank.

In various embodiments, PPR hardware can be inserted in a controller of a memory device. The inserted PPR hardware can be one or more storage elements integrated in an application-specific integrated circuit (ASIC) controller of a memory device. The one or more storage elements can be realized by one or more buffers or caches. Herein, a buffer or cache configured as PPR hardware dedicated to memory resource repair directly by the controller of the memory device is referred to as a buffer/cache (BC). A memory device includes one or more memory media and a controller with the controller coupled to the one or more memory media. The memory device can be interfaced with a host via an link external to the memory device and host. One or more BCs can be realized by a single SRAM or multiple SRAMs inserted in a controller, such as an ASIC controller. Alternatively, the one or more BCs can be external to the controller and coupled to the controller without signals routed through the one or more memory media to the controller of the memory device. With the PPR hardware including the BCs in the controller of a memory device, repair of memory locations of the one or more memory media of the memory device can be simplified. With a SRAM used as BC for repair execution, additional resources are effectively provided without increasing PPR resources from the one or more memory media of the memory device. This approach can simplify the repair phase in addition to standard PPR, allowing reuse of components, especially in case of a lack of availability of PPR component resources.

The use of BCs in the controller of a memory device dedicated to repair can increase overall reliability, availability, serviceability (RAS) features of the memory device because it increments the number of PPR resources and speeds up execution flow. The resource replacement provided by an arrangement of BCs in the controller is fast and fully managed by the controller. Content in PPR with BC (PPR-BC) can be stored in a dedicated ASIC non-volatile (NV) area according to the manner in which the controller of the memory device is implemented. The BC can replace use of a memory medium when the access is performed on an address corresponding to a replaced address of the memory device. Repair can be triggered by the controller based on a set of collected correctable error (CE) events or specific tests performed during run time.

The memory device can be realized in a number of different memory device architectures. For example, a BC arrangement in a controller of a memory device can be conducted in, but is not limited to, a compute express link (CXL) memory device, a solid-state drive (SSD), or other memory device. One or more memory devices may be coupled to a host, for example, a host computing device, to store data, commands, and/or instructions for use by the host while the computer or electronic system is operating. Data, commands, or instructions can be transferred between the host and the one or more memory devices during operation of a computing system or other electronic system.

Various protocols or standards can be applied to facilitate communication between a host and one or more other devices such as memory devices, memory buffers, accelerators, or other input/output devices. For example, an unordered protocol such as CXL can be used to provide high-bandwidth and low-latency connectivity. Other protocols can be used alternatively to or in conjunction with CXL.

CXL is an open standard interconnect configured for high-bandwidth, low-latency connectivity between host devices and other devices such as accelerators, memory buffers, and other input/output (I/O) devices. CXL was designed to facilitate high-performance computational workloads by supporting heterogeneous processing and memory systems. CXL enables coherency and memory semantics on top of peripheral component interconnect express (PCIe)-based I/O semantics for optimized performance.

CXL can be used in applications such as artificial intelligence, machine learning, analytics, cloud infrastructure, edge computing devices, communication systems, and elsewhere. Data processing in such applications can use various scalar, vector, matrix, and spatial architectures that can be deployed in a central processing unit (CPU), a graphics processing unit (GPU), a field-programmable gate array (FPGA), a digital signal processors (DSP), an ASIC, other programmable logic devices, smart network interface cards (NICs), or other accelerators that can be coupled using a CXL link. A processing module, such as a CPU, can be realized as a host device or host processor in the architecture in which the CPU is structured.

CXL supports dynamic multiplexing using a set of protocols that includes input/output (CXL.io, based on PCIe), caching (CXL.cache), and memory (CXL.memory) semantics. CXL can be used to maintain a unified, coherent memory space between the CPU and any memory on the attached CXL device. This configuration allows the CPU and the CXL device to share resources and operate on the same memory region for higher performance, reduced data movement, and reduced software stack complexity. In an example, the CPU can be primarily responsible for maintaining or managing coherency in a CXL environment. Accordingly, CXL can be leveraged to help reduce device cost and complexity, as well as overhead traditionally associated with coherency across an I/O link.

CXL runs on PCIe physical layer (PHY) and provides full interoperability with PCIe. A CXL device can start link training with a PCIe generation one data rate and can negotiate CXL as its operating protocol if its link partner supports CXL. CXL can be used as an operating protocol, for example, using an alternate protocol negotiation mechanism defined in the PCIe 5.0 specification. Devices and platforms can thus more readily adopt CXL by leveraging the PCIe infrastructure without having to design and validate the PHY, channel, channel extension devices, or other upper layers of PCIe.

CXL technology can maintain memory coherency between the CPU memory space and memory on attached devices, which enables resource sharing for higher performance, reduces software stack complexity, and lowers overall system cost. Three primary types of devices can employ a CXL interconnect protocol. Type 1 devices can include accelerators such as smart network interface controllers (NICs) that typically lack local memory. Via CXL, these type 1 devices can communicate with memory of the host processor to which it is coupled. Type 1 devices can use CXL.io+CXL.cache protocols. Type 2 devices can include GPUs, ASICs, and FPGAs that are equipped with instrumentalities such as, but not limited to, double data rate (DDR) memory or high bandwidth memory (HBM) and can use CXL to make the memory of the host processor locally available to an accelerator and make the memory of the accelerator locally available to the host processor. The type 2 devices can also be co-located in the same cache-coherent domain and help boost heterogeneous workloads. Type 2 devices can use CXL.io+CXL.cache+CXL.memory protocols. Type 3 devices can include memory devices that can be attached via CXL to provide additional bandwidth and capacity to host processors. The type of memory is independent of the main memory of the host. Type 3 devices can use CXL.io+CXL.memory protocols.

In various embodiments, one or more BCs integrated with a controller effectively provide additional availability of spare resources. With such spare resources, it is possible to increase the device lifetime, enabling the reuse of aged memory medium components in memory devices, such as but not limited to DRAM components in CXL memory devices. Such approaches can be applied to any DRAM system, such as but not limited to a fourth generation of double data rate RAM (DDR4) registered dual in-line memory module (RDIMM), without any performance impact. These approaches can be applied as well to other types of memory technology such as but not limited to NAND technology. In addition, these approaches can be implemented with different granularities. An entire virtual row can be repaired, or just a failed row of a specific device can be repaired. A virtual page can be repaired or just the failed page of a specific device can be repaired. In addition, controllers with one or more BCs can be implemented in one of several different architectures. For example, a single BC can be implemented for a memory device, a single BC can be implemented per channel of a memory device, or a single BC can be implemented per channel and rank of a memory device.

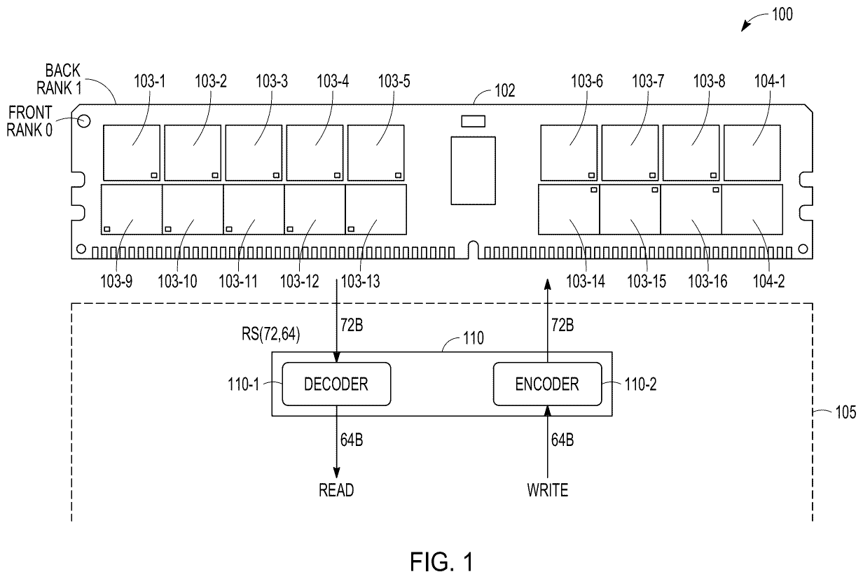

FIG. 1 illustrates an application of a DDR4 RDIMM 102 dual rank structure, which has dual rank 0/1 for the module, where one rank is accessible at a time, in a memory device including a controller 105. A rank of memory is a subset of memory chips, such as DRAM chips, in a memory module that operate in adherence in response to a given command, where all chips comprising a rank are controlled at the same time. The chips of the same rank can share an address bus and a command bus but provide different data. For example, rank 0 of DDR4 RDIMM 102, on a front side of DDR4 RDIMM 102, includes eighteen dice with sixteen dice 103-1 . . . 103-16 for data storage and two dice 104-1 and 104-2 for parity. Rank 1 of DDR4 RDIMM 102, on the back side of DDR4 RDIMM 102, can be structured in the same manner as rank 0. Each of the front side and the back side of DDR4 RDIMM 102 can have seventy-two pins with four pins per each die.

A set of memory media that stores data, such as DDR4 RDIMM 102, can be arranged with respect to other format parameters such as a bank, channel, and other formats. A bank is a set of independent arrays inside a DRAM chip. Each bank of memory is an independent array that can be in different phases of a data access/refresh cycle. A channel is a connection path between DDR4 RDIMM 102 and the memory controller for DDR4 RDIMM 102. A row is a set of storage cells responsive to a row activation command. A row activation command activates the same addressed row of a bank in all DRAM chips in a given rank of memory. A DRAM row effectively spans across the multiple DRAM chips of a given set of memory medium. A column of data is the smallest addressable unit of memory. In response to a column access command, multiple columns of data are fetched, depending on the programmed burst length. Burst length is the amount of data read or written after a respective read or write command. In the example of FIG. 1, the burst length can be eight presenting 64 B of data (4 B for each of the 16 dice for data storage) plus 8 B of parity (4 B for each of the 2 Dice for parity).

Data from a host is written to and read from DDR4 RDIMM 102 by controller 105 using a set of decoder/encoder 110 for error correction including parity generation. Each decoder/encoder 110 can include a decoder 110-1 and an encoder 110-2. Decoder 110-1 and encoder 110-2 can be implemented as a single entity. Decoder/encoder 110 can be implemented as a Reed-Solomon (RS) decoder/encoder, which is a set of error-correcting codes. A RS decoder/encoder can be structured as a RS(Y,X) decoder/encoder for X bytes of data and Y bytes of the X bytes plus a number of parity bytes Y-X. In the example of FIG. 1, a RS(72, 64) decoder/encoder is used in which 64 B are data and 8 B are parity such that on a write operation of 64 B of data, 72 B are stored in the memory media of DDR4 RDIMM 102, and on a read operation to retrieve 64 B of data, 72 B are fetched from DDR4 RDIMM 102.

DDR4 RDIMM 102 can be used to include a PPR resource. In the example of FIG. 1, with sixteen banks per memory medium die and one PPR resource per bank, the PPR resource for DDR4 RDIMM 102 can have a 512 B row size. The PPR resource provides a storage location in which to move data from memory medium locations of the DDR4 RDIMM 102 that are the subject of repair. To provide enhanced capacity, flexibility, and speed in repair procedures, one or more BCs can be structured as a part of controller 105 to store the data of the failing memory medium locations of the DDR4 RDIMM 102, without using capacity of the memory medium of the DDR4 RDIMM 102. The one or more BCs can be one or more SRAMs inserted in controller 105 that operates with and external to DDR4 RDIMM 102.

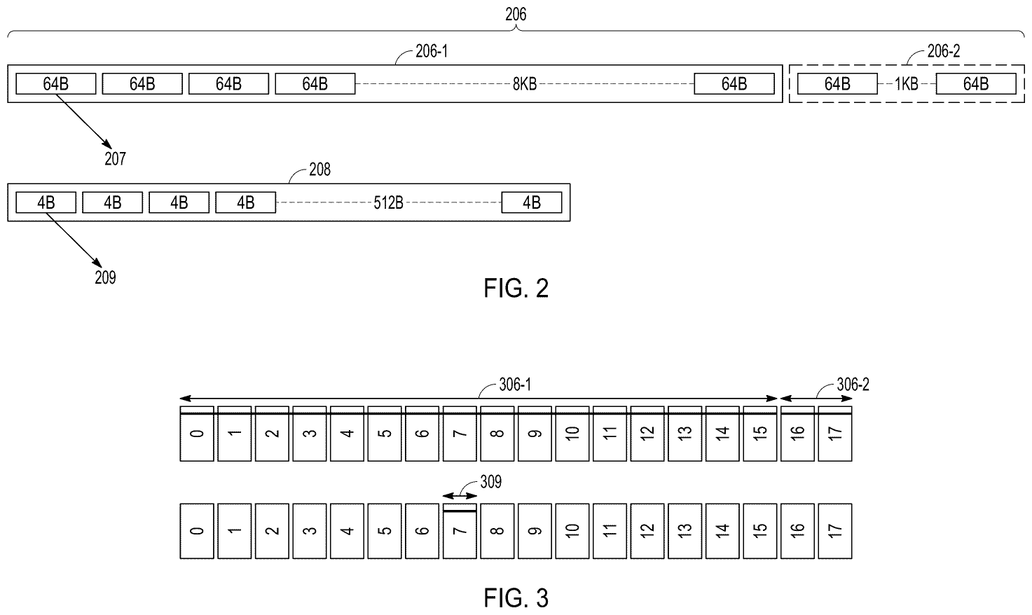

FIG. 2 illustrates a virtual row 206 and a physical row 208 for a memory medium. Virtual row 206 can be composed of a data section 206-1 and a parity section 206-2, with each of data section 206-1 and parity section 206-2 having virtual pages. In this example, data section 206-1 includes 8 KB of data organized in virtual pages with each virtual page 207 having 64 B, and parity section 206-2 includes 1 KB of data organized in virtual pages with each virtual page 209 having 64 B. Virtual row 206 (8 KB+1 KB) is composed of 128+16 virtual pages (64 B), depending on parity information. A virtual row can be mapped per a host command. Virtual page 207 is the data (64 B) of a data line (BL) spread across multiple dice present on a rank, such as rank 0/1 of DDR4 RDIMM 102 of FIG. 1. Physical row 208 is the physical bank row. In the example of FIG. 2, physical row 208 is a row of 512 B and is composed of 128 pages, where each page 209 of the physical row is a page of 4B.

In a virtual approach of integrating PPR resources in a controller, all data or parity can be served from a BC of a controller. Parity can be present or not present in the BC, depending on the configuration of the BC in the controller architecture. In a physical approach of integrating PPR resources in a controller, data or parity can be served from a BC of a controller and memory medium, such as DRAM. A page in a physical approach can be a data page or parity page.

FIG. 3 illustrates a virtual row and a physical row of a DDR4 RDIMM with respect to a command from a host. At a device physical address (DPA), data associated with a 64 B command is spread across all dice of the DDR4 RDIMM, 4 B for each die. With sixteen dice of the DDR4 RDIMM, there is 4 B of data for each of sixteen die in data structure 307-1 and 4 B of ECC parity for two die in data structure 307-2 spread across all the dice. The physical row size of a die of the DDR4 RDIMM can be 512 B, which can be provided by 128 columns of 4 B, providing a data section 306-1 of 16×512 B=8 KB. A priority section 306-2 provides 2×512 B=1 KB of priority data. For a virtual row, 64 B of data of the command can be fully placed in a BC integrated in a controller. The controller can be an ASIC controller, such as an ASIC CXL controller, in which the data can be fully placed in a core controller of the ASIC controller. In the BC, 1 KB of ECC data can be present, if the architecture of the controller to interact with the DDR4 RDIMM includes the BC placed between a decoder/encoder arrangement and a memory medium of the DDR4 RDIMM. The decoder/encoder arrangement can be a RS(Y,X) arrangement.

For 64 B of data of a command at a DPA, a single row and a single column can be addressed on all dice inside the same bank. Each column related to a single die provides 4 B. In DDR4, a single DPA is divided across 16 dice of data (4 B×16), while the parity data 8 B is divided across the additional two dice (4 B×2). A physical row, configured with a page 309 of 512 B related to a die, can be placed in the BC. The physical row size of 512 B is provided by 128 columns with 4 B for each column. Only 4 B from a 64 B CMD can be served from the integrated BC in a controller for the DDR4 RDIMM, while the other 68 B are served from the memory medium of the DDR4 RDIMM. Parity information can be present if the architecture of the controller to interact with the DDR4 RDIMM includes the BC placed between a decoder/encoder arrangement and a memory medium of the DDR4 RDIMM. The decoder/encoder arrangement can be a RS(Y,X) arrangement.

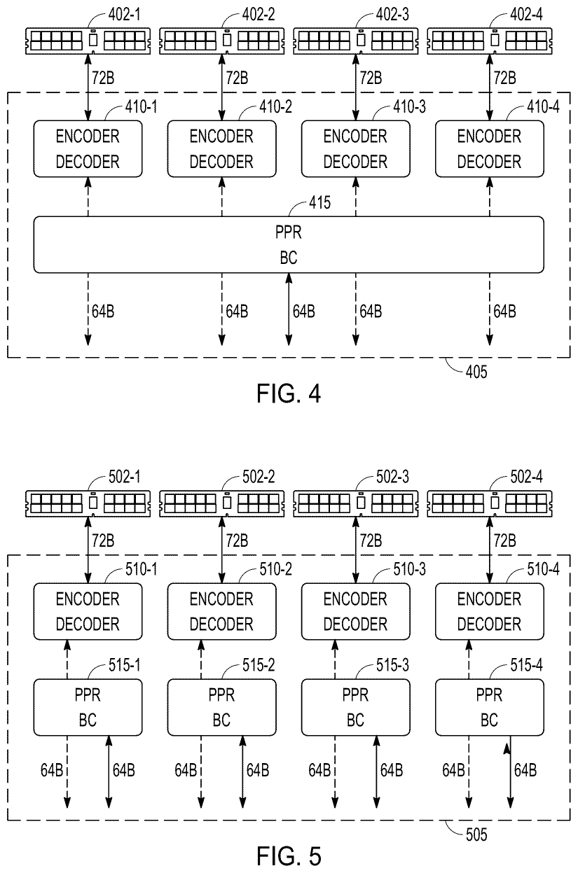

FIG. 4 illustrates an embodiment of an example of a BC arrangement in a controller 405 to provide PPR resources for modules 402-1, 402-2, 402-3, and 402-4 of memory media in a virtual repair situation where no parity data is needed. The memory media can be DRAMs. The PPR-BC arrangement can be used for virtual row repair, which can be, but is not limited to, a 8 KB virtual row. Though four channels are shown from controller 405 in FIG. 4, a controller can have an arrangement similar to that of FIG. 4 with more or fewer than four channels and four modules of memory media. Controller 405 can be include an encoder/decoder 410-1 coupled to module 402-1, an encoder/decoder 410-2 coupled to module 402-2, an encoder/decoder 410-3 coupled to module 402-3, and an encoder/decoder 410-4 coupled to module 402-4. The number of encoder/decoders can equal the number of modules of memory media. Each of encoder/decoder 410-1, encoder/decoder 410-2, encoder/decoder 410-3, and encoder/decoder 410-4 can be, but is not limited to, a RS(Y,X) encoder/decoder.

Controller 405 includes a PPR BC 415 structured with each of encoder/decoder 410-1, encoder/decoder 410-2, encoder/decoder 410-3, and encoder/decoder 410-4 between PPR BC 415 and modules 402-1, 402-2, 402-3, and 402-4 of memory media. PPR BC 415 is in a shared BC arrangement. With PPR BC 415 before encoder/decoder 410-1, encoder/decoder 410-2, encoder/decoder 410-3, and encoder/decoder 410-4 for read and write operations from and to modules 402-1, 402-2, 402-3, and 402-4 of memory media, PPR BC 415 is shared across channels by modules 402-1, 402-2, 402-3, and 402-4 of memory media. In this arrangement, 64 B can be provided to and out of PPR BC 415 in a virtual repair situation, while 72 B can be provided to and out of modules 402-1, 402-2, 402-3, and 402-4 of memory media. In this BC arrangement, there is no parity management. When data is accessed by a command from an external host, PPR BC 415 is initially checked and if the address is present (a HIT), the data are read/written to the PPR BC, otherwise (a MISS), the data is accessed from modules 402-1, 402-2, 402-3, and 402-4 of memory media. In this configuration, no BC data is merged with data of memory media because the entire virtual row 8 KB (512 B×16), corresponding to 128 columns (4 B) for each die, is moved in the PPR-BC.

FIG. 5 illustrates an embodiment of an example of a BC arrangement in a controller 505 to provide PPR resources for modules 502-1, 502-2, 502-3, and 502-4 of memory media in a virtual repair situation. The memory media can be DRAMs. The PPR-BC arrangement can be used for virtual row repair, which can be, but is not limited to, an 8 KB virtual row. Though four channels are shown from controller 505 in FIG. 5, a controller can have an arrangement similar to that of FIG. 5 with more or fewer than four channels and four modules of memory media. Controller 505 includes an encoder/decoder 510-1 coupled to module 502-1, an encoder/decoder 510-2 coupled to module 502-2, an encoder/decoder 510-3 coupled to module 502-3, and an encoder/decoder 510-4 coupled to module 502-4. The number of encoder/decoders can equal the number of modules of memory media. Each of encoder/decoder 510-1, encoder/decoder 510-2, encoder/decoder 510-3, and encoder/decoder 510-4 can be, but is not limited to, a RS(Y,X) encoder/decoder.

Controller 505 includes a PPR BC 515-1, a PPR BC 515-2, a PPR BC 515-3, and a PPR BC 515-4. PPR BC 515-1, PPR BC 515-2, PPR BC 515-3, and PPR BC 515-4 are in a non-shared arrangement. PPR BC 515-1 is coupled to encoder/decoder 510-1, with encoder/decoder 510-1 between PPR BC 515-1 and module 502-1 of memory media. PPR BC 515-2 is coupled to encoder/decoder 510-2, with encoder/decoder 510-2 between PPR BC 515-2 and module 502-2 of memory media. PPR BC 515-3 is coupled to encoder/decoder 510-3, with encoder/decoder 510-3 between PPR BC 515-3 and module 502-3 of memory media. With PPR BC 515-1, PPR BC 515-2, PPR BC 515-3, and PPR BC 515-4 structured before encoder/decoder 510-1, encoder/decoder 510-2, encoder/decoder 510-3, and encoder/decoder 510-4, respectively, for read and write operations from and to modules 502-1, 502-2, 502-3, and 502-4 of memory media, PPR BC 515-1, PPR BC 515-2, PPR BC 515-3, and PPR BC 515-4 are not shared across channels by modules 502-1, 502-2, 502-3, and 502-4 of memory media. In this arrangement, 72 B can be provided to and out of modules 502-1, 502-2, 502-3, and 502-4 of memory media, and 64 B can be provided to and out of PPR BC 515-1, PPR BC 515-2, PPR BC 515-3, and PPR BC 515-4 in a virtual repair situation. In this BC arrangement, there is no parity management. When data is accessed by a command from an external host, PPR BC 515-1, PPR BC 515-2, PPR BC 515-3, and PPR BC 515-4 are initially checked and if data corresponding to the command is not in PPR BC 515-1, PPR BC 515-2, PPR BC 515-3, and PPR BC 515-4, lack of occurrence of the data in PPR BC 515-1, PPR BC 515-2, PPR BC 515-3, and PPR BC 515-4 defines a MISS. Data along a data path is accessed from modules 502-1, 502-2, 502-3, and 502-4 of memory media on a MISS event and BC data is not merged with data of the memory media.

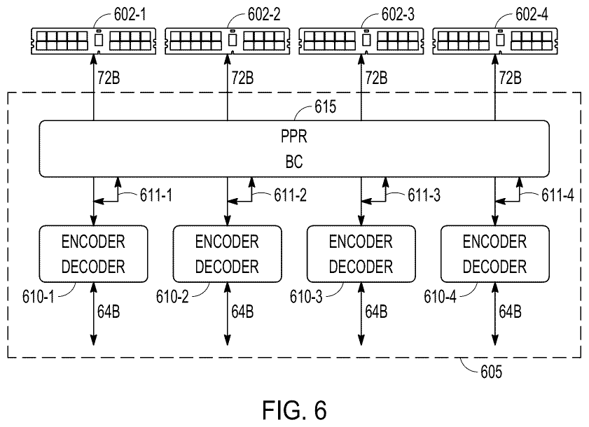

FIG. 6 illustrates an embodiment of an example of a BC arrangement in a controller 605 to provide PPR resources in a physical repair situation for multiple modules 602-1, 602-2, 602-3, and 602-4 of memory media, in which the BC arrangement is in a shared configuration. The memory media can be DRAMs. The PPR-BC arrangement can be used for physical row repair, which can be, but is not limited to, a 512 B physical row. Though four channels are shown from controller 605 in FIG. 6, a controller can have an arrangement similar to that of FIG. 6 with more or fewer than four channels and four modules of memory media. Controller 605 can include a PPR BC 615. Controller 605 can include an encoder/decoder 610-1, an encoder/decoder 610-2, an encoder/decoder 610-3, and an encoder/decoder 610-4, where encoder/decoder 610-1, encoder/decoder 610-2, encoder/decoder 610-3, and encoder/decoder 610-4 are each coupled to PPR BC 615. The number of encoder/decoders can equal the number of modules of memory media. Each of encoder/decoder 610-1, encoder/decoder 610-2, encoder/decoder 610-3, and encoder/decoder 610-4 can be, but is not limited to, a RS(Y,X) encoder/decoder.

Controller 605 includes PPR BC 615 in a shared BC arrangement and is structured between modules 602-1, 602-2, 602-3, and 602-4 of memory media and encoder/decoder 610-1, encoder/decoder 610-2, encoder/decoder 610-3, and encoder/decoder 610-4. With PPR BC 615 after encoder/decoder 610-1, encoder/decoder 610-2, encoder/decoder 610-3, and encoder/decoder 610-4 for read and write operations from and to modules 602-1, 4602-2, 602-3, and 602-4 of memory media, PPR BC 615 is shared across channels by modules 602-1, 602-2, 602-3, and 602-4 of memory media. In this arrangement, 64 B can be provided to and out of PPR BC 615 to modules 602-1, 602-2, 602-3, and 602-4 of memory media in a physical repair situation, and 64 B can be provided to and out of encoder/decoder 610-1, encoder/decoder 610-2, encoder/decoder 610-3, and encoder/decoder 610-4. When data is accessed by a command from an external host, PPR BC 615 is initially checked, and if data corresponding to the command is not in PPR BC 615, lack of occurrence of the data in PPR BC 615 defines a MISS, and if data corresponding to the command is in PPR BC 615, occurrence of the data in PPR BC 615 defines a HIT. Data along a data path is accessed from modules 602-1, 602-2, 602-3, and 602-4 of memory media on a MISS event and accessed from PPR BC 415 on a HIT event. BC data as shown by paths 611-1, 611-2, 611-3, and 611-4 can be merged (at least 4 B) with data of the memory media. In the case of a single physical row in a single die can be replaced with 512 B. On a 64 B command from a host, only 4 B can be served from the BC (one column per 128 columns related to the 512 B page).

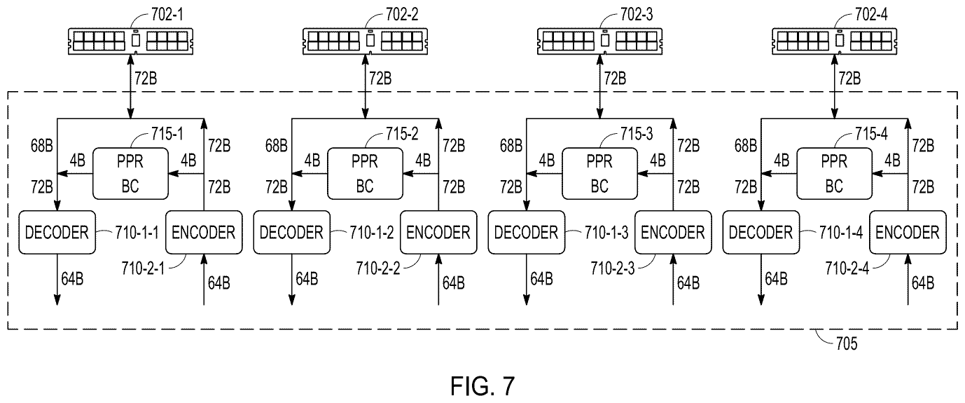

FIG. 7 illustrates an embodiment of an example of a BC arrangement in a controller 705 to provide PPR resources in a physical repair situation for multiple modules 702-1, 702-2, 702-3, and 702-4 of memory media, in which the BC arrangement is in a non-shared configuration. The memory media can be DRAMs. The PPR-BC arrangement can be used for physical repair, which can be, but is not limited to, a 512 B physical row. Though four channels are shown from controller 705 in FIG. 7, a controller can have an arrangement similar to that of FIG. 7 with more or fewer than four channels and four modules of memory media. Controller 705 includes combinations of a decoder 710-1-1 and an encoder 710-2-1, a decoder 710-1-2 and an encoder 710-2-2, a decoder 710-1-3 and an encoder 710-2-3, and a decoder 710-1-4 and an encoder 710-2-4. The number of combinations of encoders/decoders can equal the number of modules of memory media. Each of the encoders and decoders shown in FIG. 7 can be, but is not limited to, a RS(Y,X) encoders and decoders.

Controller 705 includes a PPR BC 715-1, a PPR BC 715-2, a PPR BC 715-3, and a PPR BC 715-4. PPR BC 715-1, PPR BC 715-2, PPR BC 715-3, and PPR BC 715-4 are in a non-shared arrangement. Encoder 710-2-1 and decoder 710-1-1 are coupled to PPR BC 715-1 and module 702-1 of memory media. Encoder 710-2-2 and decoder 710-1-2 are coupled to PPR BC 715-2 and module 702-2 of memory media. Encoder 710-2-3 and decoder 710-1-3 are coupled to PPR BC 715-3 and module 702-3 of memory media. Encoder 710-1-4 and decoder 710-1-4 are coupled to PPR BC 715-4 and module 702-4 of memory media.

With PPR BC 715-1, a PPR BC 715-2, a PPR BC 715-3, and a PPR BC 715-4 after encoder 710-2-1/decoder 710-1-1, encoder 710-2-2/decoder 710-1-2, encoder 710-2-3/decoder 710-1-3, and encoder 710-2-4/decoder 710-1-4, respectively, for read and write operations from and to modules 702-1, 702-2, 702-3, and 702-4 of memory media, PPR BC 715-1, PPR BC 715-2, PPR BC 715-3, and PPR BC 715-4 are not shared across channels by modules 702-1, 702-2, 702-3, and 702-4 of memory media. In this arrangement, 72 B can be provided to modules 702-1, 702-2, 702-3, and 702-4 of memory media with 4 B ECC data provided to and from PPR BC 715-2, PPR BC 715-3, and PPR BC 715-4 associated with 68B of data in a physical repair situation. Another case of repair can include the same row in the same bank on two different dice. In this case for each 72 B, 4 B×2=8 B can be allocated in a BC arrangement because there are two physical rows in the BC arrangement related to different dice.

When data is accessed by a command from an external host, PPR BC 715-1, PPR BC 715-2, PPR BC 715-3, and PPR BC 715-4 are initially checked with respect to a HIT or MISS. Data along a data path is accessed from modules 602-1, 602-2, 602-3, and 602-4 of memory media on a MISS event and accessed from PPR BC 715-1, PPR BC 715-2, PPR BC 715-3, and PPR BC 715-4 on a HIT event. BC data as shown by paths in and out of PPR BC 715-1, PPR BC 715-2, PPR BC 715-3, and PPR BC 715-4 can be merged with data of the memory media.

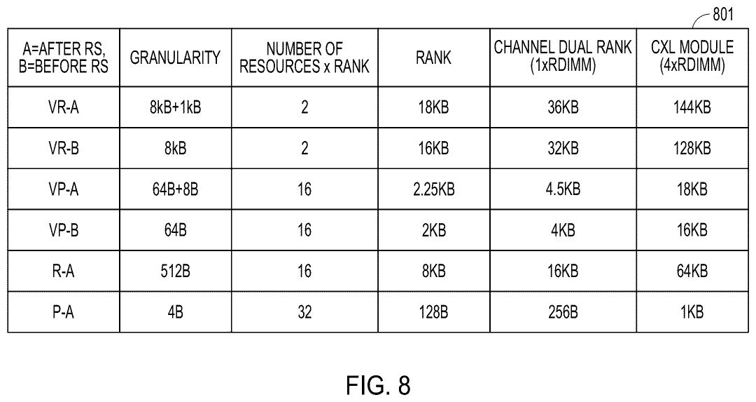

FIG. 8 shows a table 801 illustrating example options available that are associated with PPR-BC data size for an example dual rank configuration. Option A is for an architecture with a PPR-BC arrangement after an RS decoder/encoder arrangement for a virtual row (VR), a virtual page (VP), a row (R), and a page (P). Option B is for an architecture with a PPR-BC arrangement before an RS decoder/encoder arrangement for a VR, a VP, a R, and a P. For example, for the VR-A row in table 801, a single resource of granularity, which is basically a BC line, of 8 KB+1 KB=9 KB is considered having a number of resources per rank=2, with a single rank=18 KB provided, a single channel dual rank=36 KB provided, or four channel=144 KB. In the example, a full CXL module including 4×RDIMM can be provided as a maximum device density. The VR-B row, VP-A row, VP-B row, R-A row, and P-A row can be read in basically the same manner as VR-A row.

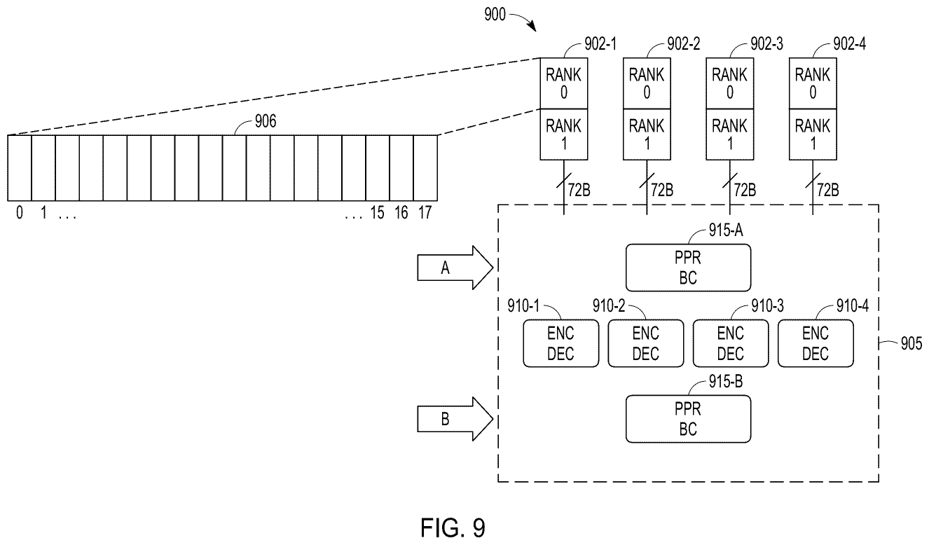

FIG. 9 illustrates a BC arrangement for a memory media configuration 900 having modules 902-1, 902-2, 902-3, and 902-4 of memory media coupled to a controller 905. Modules 902-1, 902-2, 902-3, and 902-4 are of rank 2, having a rank 0 and rank 1, which can correspond to Table 801 of FIG. 8. Each rank is composed by a number of data dice plus a number of parity die according to the memory type. In the case of DDR4, the rank 902 is composed by a row 906 having 16 dice of data and two dice of parity information. Controller 905 is shown with two BC shared options, where option A is for an architecture with a PPR-BC arrangement after an encoder/decoder structure, and option B is for an architecture with a PPR-BC arrangement before an encoder/decoder structure. Implementation of memory media configuration 900 can include one of the two options. Controller 905 can include PPR-BC 915-A (option A) or PPR-BC 915-B (option B) in shared operation with an encoder (ENC)/decoder (DEC) 910-1, an encoder/decoder 910-2, an encoder/decoder 910-3, and an encoder/decoder 910-4 for writes and reads associated with data related to modules 902-1, 902-2, 902-3, and 902-4, respectively. Though data associated with the memory modules is shown as 72 B, other quantities can be used depending on parameters of the memory media configuration implemented.

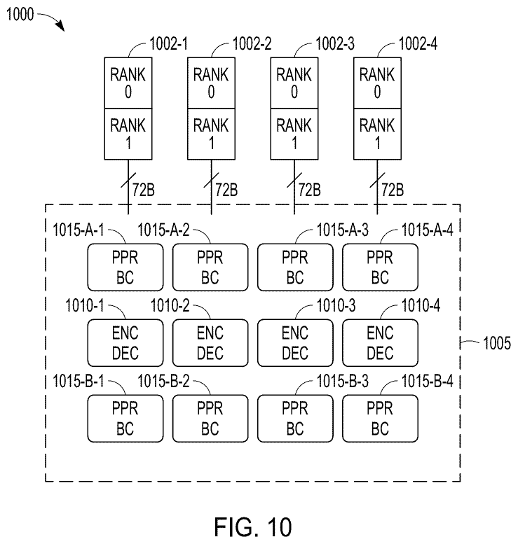

FIG. 10 illustrates a BC in a non-shared arrangement for a memory media configuration 1000 having modules 1002-1, 1002-2, 1002-3, and 1002-4 of memory media coupled to a controller 1005 with single channels. Modules 1002-1, 1002-2, 1002-3, and 1002-4 are of rank 2, having a rank 0 and rank 1, which can correspond to Table 801 of FIG. 8. Each rank can include row 906 of FIG. 9, having 16 dice of data and two dice of parity information. Controller 1005 is shown with two BC non-shared options, where option A is for an architecture with a PPR-BC arrangement after an encoder/decoder structure, and option B is for an architecture with a PPR-BC arrangement before an encoder/decoder structure. Implementation of memory media configuration 1000 can include one of the two options. Controller 1005 can include a set of BCs including PPR-BC 1015-A-1, PPR-BC 1015-A-2, PPR-BC 1015-A-3, and PPR-BC 1015-A-4 (option A) or a set of BCs including PPR-BC 1015-B-1, PPR-BC 1015-B-2, PPR-BC 1015-B-3, and PPR-BC 1015-B-4 (option B) in non-shared operation with an encoder/decoder 1010-1, an encoder/decoder 1010-2, an encoder/decoder 1010-3, and an encoder/decoder 1010-4 for writes and reads associated with data related to modules 1002-1, 1002-2, 1002-3, and 1002-4, respectively. Though data associated with the memory modules is shown as 72 B, other quantities can be used depending on parameters of the memory media configuration implemented.

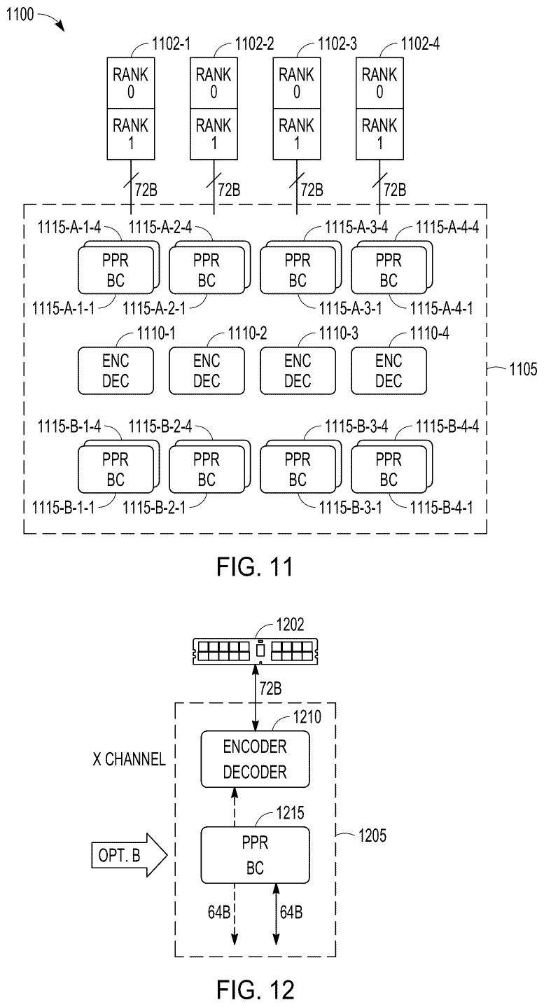

FIG. 11 illustrates a BC arrangement for a memory media configuration 1100 having modules 1102-1, 1102-2, 1102-3, and 1102-4 of memory media coupled to a controller 1105 with four channels. Modules 1102-1, 1102-2, 1102-3, and 1102-4 are of rank 2, having a rank 0 and rank 1, which can correspond to Table 801 of FIG. 8. Each rank can include row 906 of FIG. 9, having 16 dice of data and two dice of parity information. Controller 1105 is shown with two BC non-shared options, where option A is for an architecture with a PPR-BC arrangement after an encoder/decoder structure an option B is for an architecture with a PPR-BC arrangement before an encoder/decoder structure. Implementation of memory media configuration 1100 can include one of the two options. Controller 1105 can include sets of BCs having PPR-BC 1115-A-1-1 . . . . PPR-BC 1115-A-1-4, PPR-BC 1115-A-2-1 . . . . PPR-BC 1115-A-2-4, PPR-BC 1115-A-3-1 . . . . PPR-BC 1115-A-3-4, and PPR-BC 1115-A-4-1 . . . . PPR-BC 1115-A-4-4 (option A) or sets of BCs having PPR-BC 1115-B-1-1 . . . . PPR-BC 1115-B-1-4, PPR-BC 1115-B-2-1 . . . . PPR-BC 1115-B-2-4, PPR-BC 1115-B-3-1 . . . . PPR-BC 1115-B-3-4, and PPR-BC 1115-B-4-1 . . . . PPR-BC 1115-B-4-4 (option B) in non-shared operation with encoder/decoder 1110-1, encoder/decoder 1110-2, encoder/decoder 1110-3, and encoder/decoder 1110-4 for writes and reads associated with data related to modules 1102-1, 1102-2, 1102-3, and 1102-4, respectively. The sets of BCs can include a number of BCs equal to the number of channels to the respective module of memory media. Though data associated with the memory modules is shown as 72 B, other quantities can be used depending on parameters of the memory media configuration implemented.

FIG. 12 illustrates an embodiment of an example of a single channel, x channel, between a module 1202 of memory media and a controller 1205. Controller 1205 can include an encoder-decoder 1210 and a PPR-BC 1215. Data provided from controller 1205 can be, but is not limited to, 72 B, depending on the design used, where 72 B includes 64 B of data and 8 B of parity information. FIG. 12 shows the option B of FIG. 8. If there is no HIT with respect to the 64 B input to PPR-BC 1215, based on an address from a host, the 64 B input is provided to encoder/decoder 1210, which processes the 64 B to generate parity information that is combined with the 64 B for loading into the memory media of module 1202. If the address from the host corresponds to a mapping in PPR-BC 1215, the 64 B can be stored in a PPR resource of PPR-BC 1215.

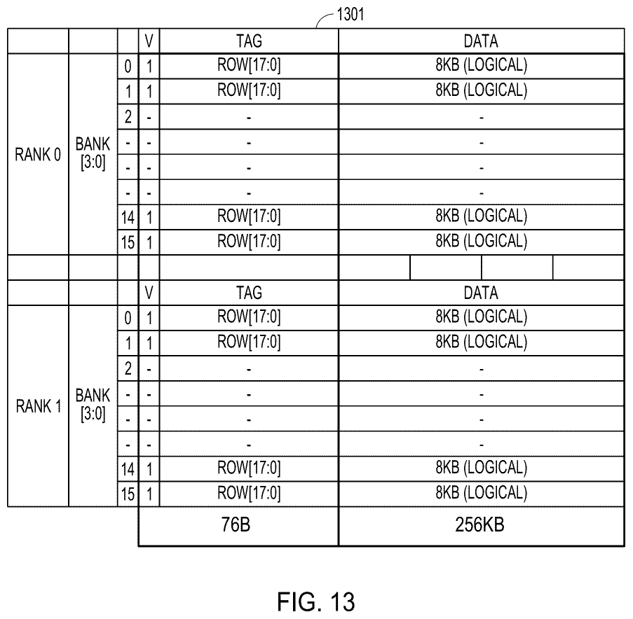

FIG. 13 illustrates an embodiment of an example of direct map per DDR4 rank (16 banks per die) upon reception of an address from a host in the example structure of FIG. 12 and table 801 of FIG. 8 with option VR-B with 8 KB but with 16 resources per rank. In this example, a single PPR virtual row per bank can be implemented with single rows in a PPR-BC with a total of sixteen rows per PPR-BC per rank, such as in PPR-BC 1215. A dual rank RDIMM is used as reference in which a row of the PPR-BC can include 19 b of metadata plus 8 KB of data per PPR resource. As shown in FIG. 13, valid bit (V) is metadata, with 19 b×32 resources=608 b=76 B. V equals zero at power-up and is set to 1 when the row is used, which is when the VR is moved from the memory media to inside the PPR-BC. The example includes two ranks (0/1) and for each rank there are sixteen resources, rows 0-15 in a representation 1301 of a mapping table, one for each bank. The 19 b of metadata per row of mapping table in PPR-BC 1215 can be a tag that identifies the address of a row in module 1202 of memory media for which PPR-BC 1215 provides a PPR resource plus a valid bit to indicate that the resource was used. The 8 KB following the 19 b of metadata in the data structure of the row in PPR-BC 1215 is allocated to contain data to be stored in the failed location having the address of the row in module 1202 of memory media for which PPR-BC 1215 provides the PPR resource. In direct mapping, when an address is received from a host, the rows related to the bank of the address are examined, for example a received address of bank 5 (row=5) and row [17:0] is compared with the TAG in the mapping table for a HIT or a MISS.

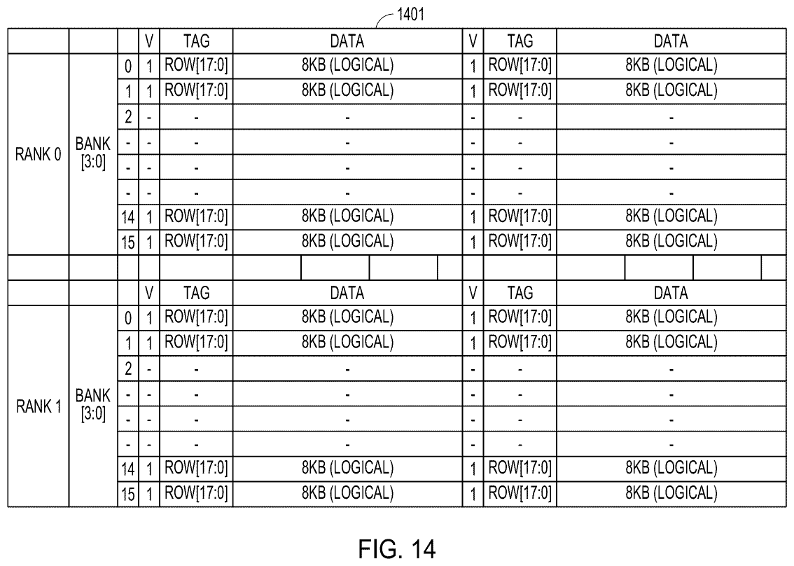

FIG. 14 illustrates an embodiment of an example of a two-way set associative mapping per rank upon reception of an address from a host in the example structure of FIG. 12 and table 801 of FIG. 8 with option VR-B with 8 KB but with 32 resources per rank (two per bank). In this example, a single PPR virtual row per bank can be implemented in a single row/single way with sixteen rows per PPR-BC, such as in PPR-BC 1215. In this example, the virtual row is 8 KB of data and can be placed in way 0 (a first row of a given bank) or way1 (a second row of the given bank) with the related TAG. A dual rank RDIMM is used as reference in which a row of the PPR-BC can include 19 b of metadata plus 8 KB of data per PPR resource with total of 38 b of metadata plus 16 KB of data per row. As shown in FIG. 14, the example includes two ranks (0/1) and for each rank there are thirty-two resources, rows 0-15 in a representation 1401 of mapping table, two for each bank. The 19 b of metadata per row/way of the mapping table in PPR-BC 1215 can be a tag that identifies the address of a row in module 1202 of memory media for which PPR-BC 1215 provides a PPR resource. The 8 KB following the 19 b of metadata in the data structure of the row in PPR-BC 1215 is allocated to contain data to be stored in the failed location having the address of the row in module 1202 of memory media for which PPR-BC 1215 provides the PPR resource. Two-way set associative mapping basically is a direct mapping, but two tags are compared in parallel. In two-way set associative mapping, when an address is received from a host, the rows related to the bank of the address are examined, for example a received address of bank 5 (row=5) is compared with two tag fields in the same row=5 in the mapping table for a HIT or a MISS.

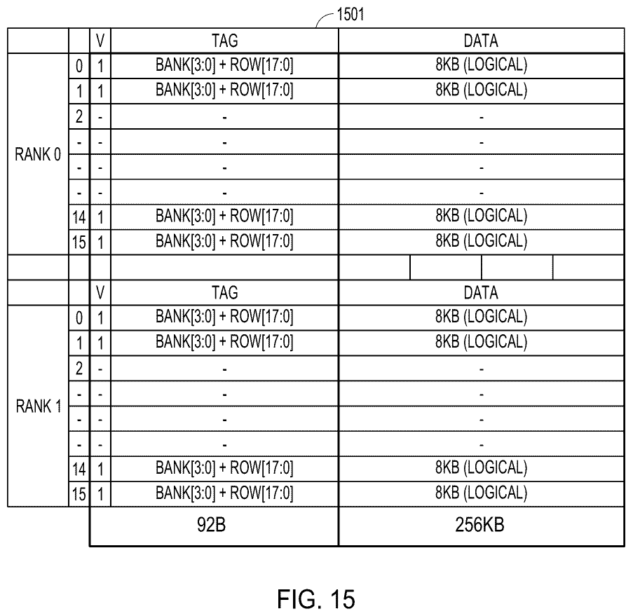

FIG. 15 illustrates an embodiment of an example of a fully associative mapping per rank upon reception of an address from a host in the example structure of FIG. 12 and table 801 of FIG. 8 with option VR-B with 8 KB but with 16 resources per rank. In this example, a single PPR virtual row per bank can be implemented with a single row in the PPR-B C with a total of sixteen rows per PPR-BC, such as in PPR-BC 1215. A dual rank RDIMM is used as reference in which a row of the PPR-BC can include 23 b of metadata plus 8 KB of data per PPR resource, with PPR rows shared across the banks. As shown in FIG. 15, the example includes two ranks (0/1) and for each rank there are sixteen resources, rows 0-15 in a representation 1501 of a mapping table. There is no fixed number per bank. It is a fully associative and the association can be different, for example, four on Bank 0 and twelve on Bank 5. The 23 b of metadata per row of the mapping table in PPR-BC 1215 can be a tag that identifies the address of a row in module 1202 of memory media for which PPR-BC 1215 provides a PPR resource. The 8 KB following the 23 b of metadata in the data structure of the row in PPR-BC 1215 is allocated to contain data to be stored in the failed location having the address of the bank/row in module 1202 of memory media for which PPR-BC 1215 provides the PPR resource. In a fully associative mapping, every bank can be in every row, such that the bank address is part of the tag. In fully associative mapping, when an address is received from a host, the rows related to the bank of the address are examined, for example a received address of bank 5 (row=5) from a host is compared in parallel to all 16 rows of tags related to the addressed rank.

When a host sends a command on address ADD, the ADD bits are divided according to the internal memory organization of rank/bank/row. A check is made, according to the BC being direct, set-associative, or fully associative. A HIT or MISS is determined with respect to the appropriate BC row.

A PPR-BC can be filled in a number of ways. When a PPR is triggered on a target row in memory media of a memory device, all columns of data related to the target row address can be copied to the PPR-BC in the controller of the memory device. For the target row address, all column addresses associated with the target row address are at risk for failure. The triggering can be conducted by the controller of the memory device by the controller based on the set of collected CE events or optionally by or in conjunction with specific tests performed at run time. For example, flags can be used to collect a count of errors corrected in reading from and writing to the media memory in execution of commands from an external host. Future accesses to the repaired row are served totally or partially by the BC according to the implementation of a BC arrangement in the controller. Virtual row copying or row copying to the BC uses multiple read commands, depending on the memory device architecture. For example, copying to the BC can use 128 read commands corresponding to 128 column addresses.

Copying a row of data to a BC can be performed in at least two ways: a background mode and a foreground mode. In a background mode, an entry related to the row of data is created and all commands are scheduled and executed interleaved with host commands. For example, the commands can be, but are not limited to, 128 column addresses. In a foreground mode, an entry related to the row of data is created and only one data, related to the last command that generated the PPR-BC request, is inserted in the PPR-BC. Other column data related to the same row can be inserted in the PPR-BC if requested from the host. The PPR-BCs inserted in a controller of a memory device having one or more memory media can be realized by SRAMs.

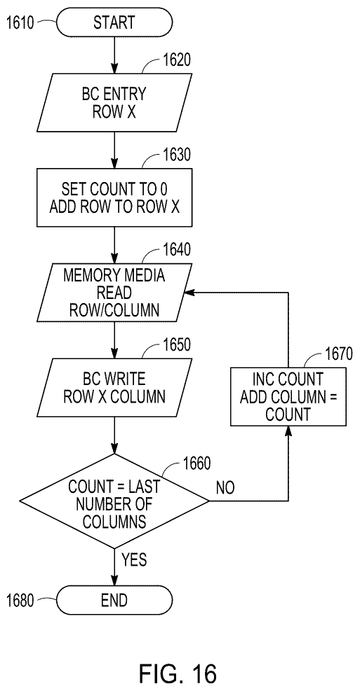

FIG. 16 is a flow diagram of an embodiment of an example PPR-BC filling in background mode of operation of a memory device. In a repair process, use of data storage locations in memory media of a memory device is replaced by other resources. In applications of one or more BCs in a controller of the memory device, data storage locations in the one or more BCs can be used as replacement resources or the memory media. At 1610, a PPR-BC filling is started with occurrence of a repair trigger. At 1620, a BC entry for the failing row of the memory media is allocated as row X in the BC. At 1630, a count is set to 0 for adding a target row of the memory media to row X, where the count set to 0 corresponds to the 0^{th} column of data for the target row. At 1640, reading of the memory media of the target row is begun according to the row and associated column. The memory media can be, but is not limited to, a DRAM.

At 1650, the data of the column of the count of the target row is written to row X in the BC. At 1660, the count is compared to the number of the last column of data of the target row. For an example DRAM, the number of the last column of data of the target row can be, but is not limited to, 127 (128 columns per row). If the count is less than the number of the last column, the count is incremented, at 1670, and the column of the incremented count is read at 1640, and the filling continues. If the count equals the number of the last column, the filling of the PPR-BC ends at 1680.

All data related to the virtual target row is moved into the PPR-BC in the controller. Read/Write commands related to the failing row can be put on hold until the copying process from the memory media to the PPR-BC structure in the controller is completed.

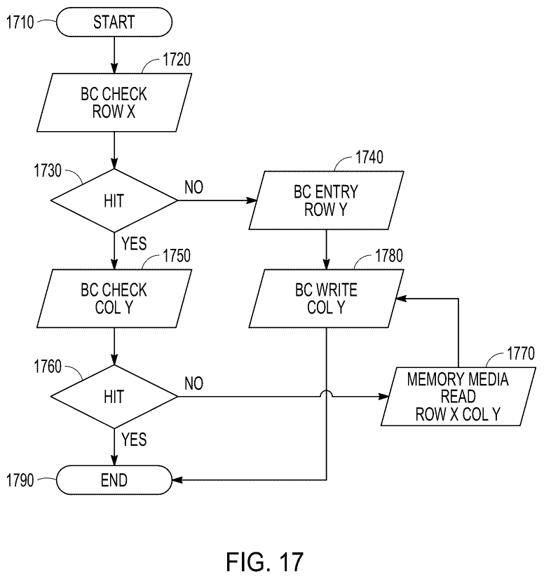

FIG. 17 is a flow diagram of an embodiment of an example PPR-BC filling in foreground mode of operation of a memory device. A virtual row of a PPR-BC is populated according to the host requests. At 1710, a PPR-BC filling is started with occurrence of a repair trigger. At 1720, the PPR-BC is checked for the presence of a row, row X, in the PPR-BC for a row in memory media of the memory device. At 1730, a determination of a HIT of row X in the PPR-BC is performed. On the HIT event occurring (Yes event), at 1750, the PPR-BC is checked for a column Y in the PPR-BC corresponding to row X. At 1760, a determination of a HIT of column Y in the PPR-BC is conducted. On the HIT event occurring (Yes event) at 1760, and the flow can end at 1790 without any access to the memory media.

If the check of the presence of row X at 1730 generates a MISS, a BC entry for the failing row of the memory media is allocated as row X in the PPR-BC. At 1780, data of a column Y corresponding to the row X is written to the PPR-BC. Only the last column data, which triggered the PPR, is written in the PPR-BC, reading the data from the media in case of read command or directly from the host in case of write command. In response to writing to column Y in PPR-BC, the flow can end at 1790.

In the foreground mode, a virtual row of a PPR-BC can be populated according to the host requests. A row HIT along with a column HIT occurs if the column is present in the PPR-BC. A column MISS occurs if the column is not present in the PPR-BC. In case of a column miss, a host command can be served from the backend and inserted in the PPR-BC.

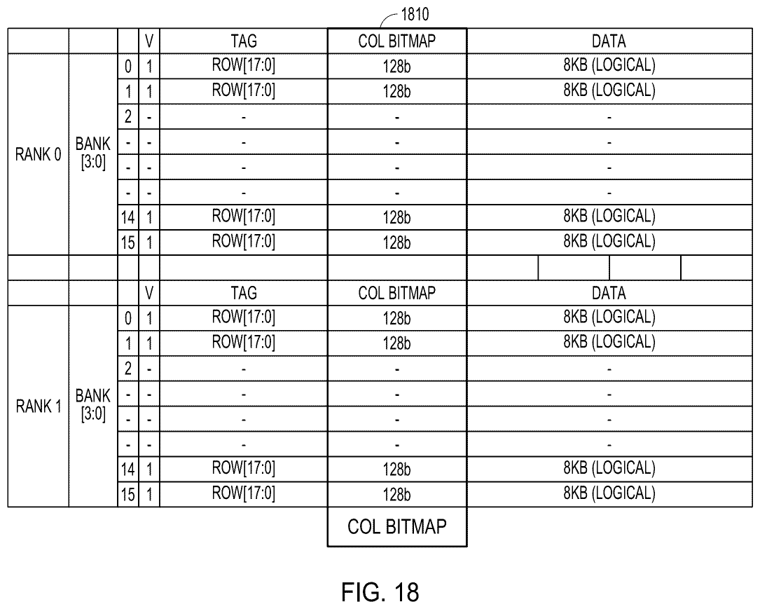

FIG. 18 illustrates an embodiment of an example of direct map per rank upon reception of an address from a host in the example structure of FIG. 12 and table 801 of FIG. 8 with option VR-B with 8 KB but with 16 resources per rank. In this example, a single PPR virtual row per bank can be implemented with sixteen rows per PPR-BC, such as in PPR-BC 1215. A dual rank RDIMM is used as reference in which a row of the PPR-BC can include 18 b of metadata plus 8 KB of data per PPR resource. As shown in FIG. 18, the example includes two ranks (0/1) and for each rank there are sixteen resources, rows 0-15 in a representation 1801 of a mapping table, one for each bank. The 19 b of metadata per row of representaton 1301 of the mapping table in PPR-BC 1215 are composed by a valid bit and a tag that identifies the address of a row in module 1202 of memory media for which PPR-BC 1215 provides a PPR resource. The 8 KB following the 19 b of metadata in the data structure of the row in PPR-BC 1215 is allocated to contain data to be stored in the failed location having the address of the row in module 1202 of memory media for which PPR-BC 1215 provides the PPR resource. The mapping table can include a column bitmap identifying which columns of the respective row are present and used during the foreground mode to fill the BC. In the example of FIGS. 17 and 18, the memory medium can be a DRAM having 128 columns per row.

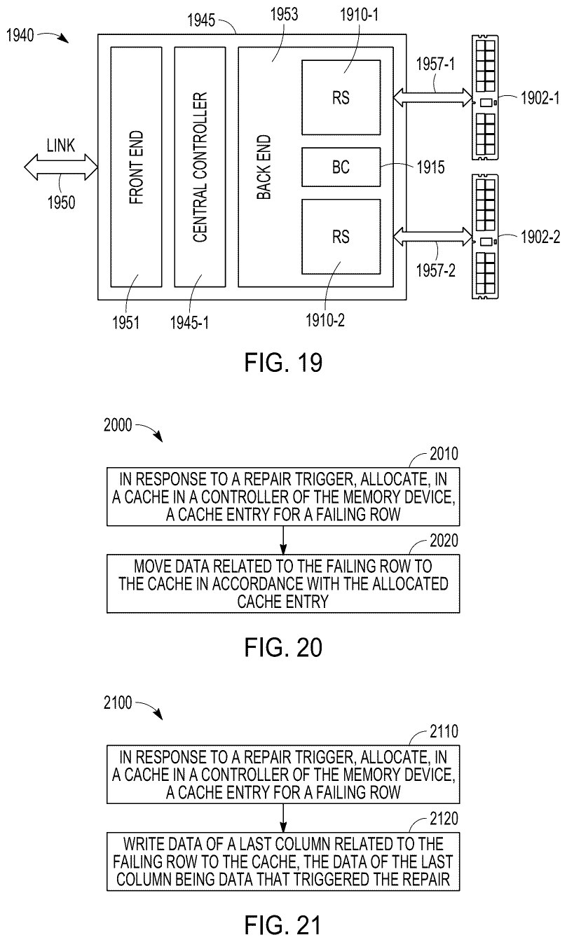

FIG. 19 illustrates an embodiment of an example two-channel DDR4 DIMM memory architecture 1940 in which a BC 1915 for PPR is integrated in a controller 1945 of memory architecture 1940. Memory architecture 1940 can couple to a host device via a link 1950 for host initiated operations, such as, but not limited to, read and write operations. Link 1950 provides commands and data to a front end of controller 1945. Controller 1945 can be coupled to a first DDR 4 DIMM 1902-1 of memory media by an interface 1957-1 and to a second DDR4 DIMM 1902-2 of memory media by an interface 1957-2. Controller 1945 can include a RS encoder-decoder 1910-1 to perform ECC operations with respect to data to and from first DDR 4 DIMM 1902-1 and a RS encoder-decoder 1910-2 to perform ECC operations with respect to data to and from second DDR 4 DIMM 1902-2. BC 1915 can be implemented with respect to RS encoder-decoder 1910-1 and RS encoder-decoder 1910-2 in accordance with an option A or option B arrangement as discussed herein. BC 1915 can be implemented with respect to RS encoder-decoder 1910-1 and RS encoder-decoder 1910-2 in a back end 1953 coupled between a central controller 1945-1 of controller 1945 and both DDR 4 DIMM 1902-1 and DDR 4 DIMM 1902-2.

FIG. 20 is a flow diagram of features of an embodiment of an example method 2000 of operating a memory device. At 2010, in response to a repair trigger, a cache entry for a failing row is allocated in a cache in a controller of the memory device. The repair trigger can be based on a set of collected correctable error events. The failing row is in memory media of the memory device. At 2020, data related to the failing row is moved to the cache in accordance with the allocated cache entry.

Variations of method 2000 or methods similar to method 2000 can include a number of different embodiments that may be combined depending on the application of such methods and/or the architecture of systems including an electronic device in which such methods are implemented. Such methods can include read commands related to the failing row being delayed until the moving of the data is completed. Variations can include write commands related to the failing row being accepted and data being stored in the cache. Read commands, scheduled in a backend process and related to a column corresponding to the failed row, can be discarded.

Variations of method 2000 or methods similar to method 2000 can include moving data to include storing error correction code data in the cache. Variations can include storing parity information in the cache. The one or more caches can be realized as one or more static random-access memories in the controller dedicated to repair replacement.

FIG. 21 is a flow diagram of features of an embodiment of an example method 2100 of operating a memory device. At 2110, in response to a repair trigger, a cache entry for a failing row is allocated in a cache in a controller of the memory device. The failing row is located in memory media of the memory device. At 2120, data of a last column related to the failing row is written to the cache, where the data of the last column is data that triggered the repair.

Variations of method 2100 or methods similar to method 2100 can include a number of different embodiments that may be combined depending on the application of such methods and/or the architecture of systems including an electronic device in which such methods are implemented. Such methods can include inserting data of another column related to the failing row into the cache upon request from a host initiating the writing of the data. Variations can include, if the other column is not listed in the cache, inserting data of the other column in the cache from the memory media in a backend process.

Variations of method 2100 or methods similar to method 2100 can include allocating the cache entry by allocating the cache entry in a cache in the controller dedicated to repair replacement. The cache can be one or more static random-access memories in the controller.

In various embodiments, a memory device can include a memory subsystem and a controller coupled to the memory subsystem. The controller can be structured to control storage of user data, where the controller can have one or more caches. The one or more caches can be separate from the memory subsystem, and the controller can be arranged to use the one or more caches to provide resource replacement to the memory subsystem. The one or more caches can be integrated into the controller.

Variations of such a memory device and its features, as taught herein, can include a number of different embodiments and features that can be combined depending on the application of such memory devices, the format of such memory devices, and/or the architecture in which such memory devices are implemented. Variations of such memory devices can include the memory subsystem of such memory devices having one or more memory media and the controller of such memory devices can be configured to process user data with the one or more memory media sharing the one or more caches of such memory devices. The controller can include an individual decoder/encoder for each memory medium of the one or more memory media, with the individual decoders/encoders configured between the one or more caches and the one or more memory media.

Variations of such memory devices can include the memory subsystem of such memory devices having multiple individual memory media. The controller can have an individual decoder/encoder for each individual memory medium of the multiple individual memory media. The controller can have multiple caches and can be configured to process user data with each memory medium of the multiple individual memory media allocated to an individual cache of the multiple caches. Each individual decoder/encoder can be configured between a corresponding allocated cache and the individual memory medium corresponding to the individual decoder/encoder.

Variations of such memory devices can include the memory subsystem of such memory devices having one or more memory media. The controller of such memory devices can be configured to process user data with the one or more memory media sharing the one or more caches. The controller can have an individual decoder/encoder for each memory medium of the one or more memory media, with the one or more caches of such memory devices positioned between the individual decoders/encoders and the one or more memory media.

Variations of such memory devices can include the memory subsystem of such memory devices having multiple individual memory media. The controller of such memory devices can include an individual decoder and individual encoder for each individual memory medium of the multiple individual memory media. The controller can also have multiple caches, where each cache of the multiple caches can be allocated to an individual memory medium of the multiple individual memory media. Each allocated cache can be configured between the individual memory medium and each individual decoder and individual encoder corresponding to the individual memory medium.

Variations of such memory devices can include the one or more caches of such memory devices be realized by one or more static random-access memories. Variations of such memory devices can include the controller being an application-specific integrated circuit. Variations of such memory devices can include the controller being configured to repair one or more rows of the memory subsystem, based on a set of collected CE events, using the one or more caches.

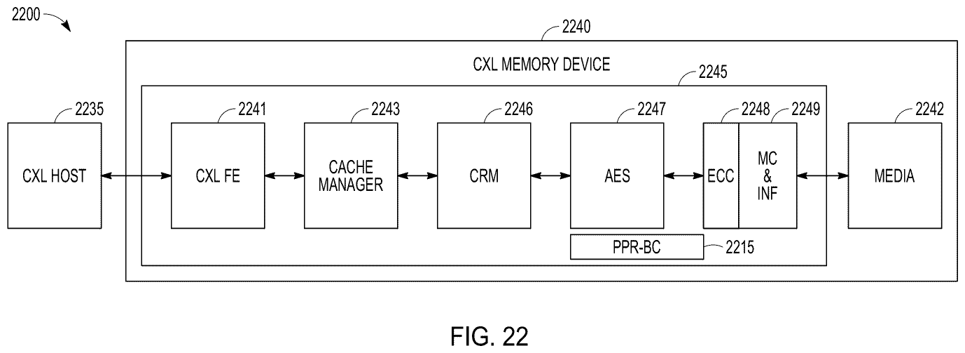

FIG. 22 is a block diagram of an embodiment of example component features of a CXL system 2200 that includes a PPR-BC 2215 integrated in a controller 2245 of a memory device 2240. PPR-BC 2215 can be a set of one or more PPR-BCs. CXL system 2200 can include a CXL host 2235 along with CXL memory device 2240 that can operate in accordance with CXL protocols. CXL memory device 2240 can include controller 2245 that interfaces with CXL host 2235 and with media 2242 of CXL memory device 2240 to write user data directed from CXL host 2235 to media 2242 using one or more write requests and to read user data from media 2242 for CXL host 2235 using one or more read requests. In response to a repair of media 2242, user data can be written into PPR-BC 2215.

Controller 2245 can include a CXL front end (FE) 2241 to interface with CXL host 2235 using CXL protocols and a cache manager 2243 to manage flow of user data associated with read and write requests received from CXL host 2235 and manage PPR-BC 2215. The user data can be stored in media 2242, where media 2242 can be structured as one or more memory structures arranged as channels of data storage. The user data can be processed with an Advanced Encryption Standard (AES) 2247 and ECC 2248. Processing of user data with ECC 2248 can be performed by a memory controller (MC) and interface (INF) 2249 that controls input and output of the user data with respect to media 2242. The user data operated on by AES 2247, ECC 2248, and MC & INF 2249 can be compressed data. Compressing user data and uncompressing user data can be controlled by a compression region manager (CRM) 2246. PPR-BC 2215 can be arranged with respect to AES 2247 and ECC 2248 in accordance with option A or option B as taught herein.

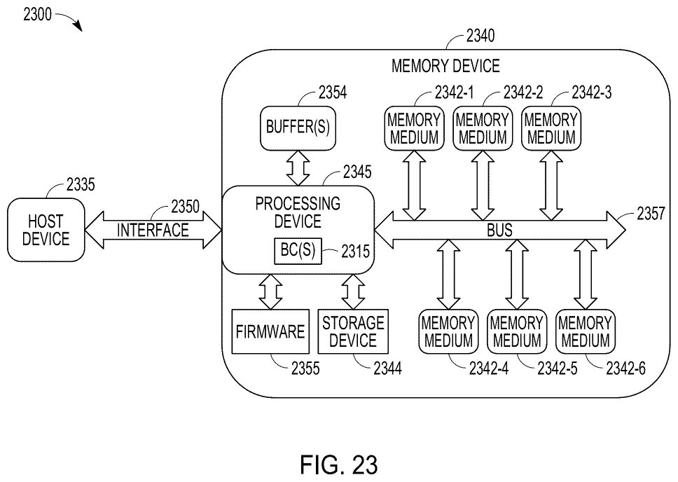

FIG. 23 is a block diagram of an embodiment of example system 2300 including a host 2335 that operates with a memory device 2340 having one or more memory media, where memory device 2340 can implement one or more BCs (BC(s)) 2315 integrated in a processing device 2345 of memory device 2340. Alternatively, BC(s) 2315 can be external and coupled to processing device 2345. BC(s) 2315 can be implemented using an architectural arrangement associated with one or more of the structures of FIGS. 4-7, 9-12, 19, and 22, the methods of FIGS. 16, 17, 20, and 21, and functions associated with one or more of the structures of FIGS. 4-7, 9-12, 19, and 22. System 2300 and its components can be structured in a number of different arrangements. For example, system 2300 can be arranged with a variation of the types of components that comprise host 2335, an interface 2350, memory device 2340, memory media 2342-1, 2342-2, 2342-3, 2342-4, 2342-5, and 2342-6, processing device 2345, BC(s) 2315, one or more buffers (buffer(s)) 2354, firmware 2355, storage device 2344, and a bus 2357.

Host 2335 can be coupled to memory device 2340 by interface 2350, where host 2335 is a host device that can comprise one or more processors, which can vary in type compatible with interface 2350 and memory device 2340. Memory device 2340 can include processing device 2345 coupled to memory media 2342-1, 2342-2, 2342-3, 2342-4, 2342-5, and 2342-6 by bus 2357, where each memory medium has one or more arrays of memory cells. Memory media 2342-1, 2342-2, 2342-3, 2342-4, 2342-5, and 2342-6 may be realized as memory structures that can be selected from different types of memory. Though six memory media are shown in FIG. 23, memory device 2340 can be implemented with more or fewer than six memory media, that is, memory device 2340 can comprise one or more memory media. The memory media can be realized in a number of formats including, but not limited to, a plurality of memory dies or a plurality of packaged memory dies.

Processing device 2345 can include processing circuitry or be structured as one or more processors. Processing device 2345 can be structured as a memory system controller for memory device 2340. Processing device 2345 can be implemented in a number of different formats. Processing device 2345 can include or be structured as one or more types of processors compatible with memory media 2342-1, 2342-2, 2342-3, 2342-4, 2342-5, and 2342-6. Processing device 2345 can include processing circuitry that can be structured with a DSP, an ASIC, other type of processing circuit, including a group of processors or multi-core devices, or combinations thereof.

Memory device 2340 can comprise firmware 2355 having code executable by processing device 2345 to at least manage the memory media 2342-1, 2342-2, 2342-3, 2342-4, 2342-5, and 2342-6. Firmware 2355 can reside in a storage device of memory device 2340 coupled to processing device 2345. Firmware 2355 can be coupled to processing device 2345 using bus 2357 or some other interface on the memory device 2340. Alternatively, firmware 2355 can reside in processing device 2345 or can be distributed in memory device 2340 with firmware components, such as, but not limited to, code, including one or more components in processing device 2345. Firmware 2355 can include code having instructions, executable by processing device 2345, to operate on memory media 2342-1, 2342-2, 2342-3, 2342-4, 2342-5, and 2342-6. The instructions can include instructions to execute operations to store user data in BC(s) 2315 in response to a triggered repair as taught herein.

Memory device 2340 can include a storage device 2344 that can be implemented to provide data or parameters used in maintenance of memory device 2340. Storage device 2344 can include one or more of a non-volatile memory structure or a RAM. Though storage device 2344 is external to processing device 2345 in memory device 2340 in FIG. 23, storage device 2344 may be integrated into processing device 2345. Storage device 2344 can be coupled to bus 2357 for communication with other components of memory device 2340. Alternatively, storage device 2344 can be coupled with processing device 2345 in which processing device 2345 handles communications between storage device 2344 and other components of the memory device 2340. Storage device 2344 can be coupled to bus 2357 and to processing device 2345.

Each of memory media 2342-1, 2342-2, 2342-3, 2342-4, 2342-5, and 2342-6, firmware 2355, storage device 2344, and other memory structures of memory device 2340 are implemented as machine-readable medium. Non-limiting examples of machine-readable media can include solid-state memories, optical media, and magnetic media. Specific examples of non-transitory machine-readable media can include non-volatile memory, such as semiconductor memory media (e.g., EPROM, EEPROM) and flash memory devices; magnetic disks, such as internal hard disks and removable disks; magneto-optical disks; and compact disc-ROM (CD-ROM) and digital versatile disc-read only memory (DVD-ROM) disks.

Firmware 2355, storage device 2344, or other components of memory device 2340 can include hardware or instructions to implement use of PPR resources as taught herein. Firmware 2355, storage device 2344, or other components of memory device 2340 can have instructions, executable by processing device 2345, to operate on user data to store the user data in one or more of BC(s) 2315. Firmware 2355, storage device 2344, or other components of memory device 2340 can have instructions, executable by processing device 2345, to operate on data with respect to BC(s) 2315.

Processing device 2345 can execute instructions stored on one or more components in memory device 2340, which instructions, when executed by processing device 2345, cause memory device 2340 to perform operations. The operations can include operations of PPR-BC filling in background mode of FIG. 16, PPR-BC filling in foreground mode of FIG. 17, method 2000, method 2100, methods similar to PPR-BC filling in background mode, PPR-BC filling in foreground mode, method 2000 or method 2100, methods associated with such methods, and functions of structures associated with FIGS. 4-7, 9-12, 19, and 22.

The following are example embodiments of devices and methods, in accordance with the teachings herein.

An example memory device 1 can comprise a memory subsystem and a controller coupled to the memory subsystem, the controller to control storage of user data. The controller can have one or more caches, where the one or more caches are separate from the memory subsystem. The controller can be arranged to use the one or more caches to provide resource replacement to the memory subsystem.

An example memory device 2 can include features of example memory device 1 and can include the memory subsystem having one or more memory media and the controller being configured to process user data with the one or more memory media sharing the one or more caches, the controller having an individual decoder/encoder for each memory medium of the one or more memory media, with the individual decoders/encoders configured between the one or more caches and the one or more memory media.

An example memory device 3 can include features of any of the preceding example memory devices and can include the memory subsystem having multiple individual memory media, the controller having an individual decoder/encoder for each individual memory medium of the multiple individual memory media, the controller having multiple caches and being configured to process user data with each memory medium of the multiple individual memory media allocated to an individual cache of the multiple caches and with each individual decoder/encoder configured between a corresponding allocated cache and the individual memory medium corresponding to the individual decoder/encoder.

An example memory device 4 can include features of any of the preceding example memory devices and can include the memory subsystem having one or more memory media and the controller being configured to process user data with the one or more memory media sharing the one or more caches, the controller having an individual decoder/encoder for each memory medium of the one or more memory media, with the one or more caches configured between the individual decoders/encoders and the one or more memory media.

An example memory device 5 can include features of any of the preceding example memory devices and can include the memory subsystem having multiple individual memory media, and the controller including: an individual decoder and individual encoder for each individual memory medium of the multiple individual memory media; and multiple caches, each cache of the multiple caches allocated to an individual memory medium of the multiple individual memory media, with each allocated cache configured between the individual memory medium and each individual decoder and individual encoder corresponding to the individual memory medium.

An example memory device 6 can include features of any of the preceding example memory devices and can include the one or more caches including one or more static random-access memories.

An example memory device 7 can include features of example memory device 6 and any of the preceding example memory devices and can include the controller being an application-specific integrated circuit.

An example memory device 8 can include features of any of the preceding example memory devices and can include the controller being configured to repair one or more rows of the memory subsystem, based on a set of collected CE events, using the one or more caches.

In an example memory device 9, any of the memory devices of example memory devices 1 to 8 may include memory devices incorporated into an electronic apparatus further comprising a host processor and a communication bus extending between the host processor and the memory device.

In an example memory device 10, any of the memory devices of example memory devices 1 to 9 may be modified to include any structure presented in another of example memory device 1 to 9.

In an example memory device 11, any apparatus associated with the memory devices of example memory devices 1 to 10 may further include a machine-readable storage device configured to store instructions as a physical state, wherein the instructions may be used to perform one or more operations of the apparatus.

In an example memory device 12, any of the memory devices of example memory devices 1 to 11 may be operated in accordance with any of the below methods 1 to 9 of operating a memory device and example methods 1 to 12 of operating a memory device.

An example method 1 of operating a memory device can comprise in response to a repair trigger, allocating, in a controller of the memory device, a cache entry for a failing row, the failing row being in memory media of the memory device; and moving data related to the failing row to the cache in accordance with the allocated cache entry.

An example method 2 of operating a memory device can include features of example method 1 of operating a memory device and can include read commands related to the failing row being put on hold until the moving of the data is completed.

An example method 3 of operating a memory device can include features of any of the preceding example methods of operating a memory device and can include write commands related to the failing row being accepted and data being stored in the cache.

An example method 4 of operating a memory device can include features of any of the preceding example methods of operating a memory device and can include responding to the repair trigger based on a set of collected CE events.

An example method 5 of operating a memory device can include features of any of the preceding example methods of operating a memory device and can include moving data to include storing error correction code data in the cache.

An example method 6 of operating a memory device can include features of any of the preceding example methods of operating a memory device and can include storing parity information in the cache.

An example method 7 of operating a memory device can include features of any of the preceding example methods of operating a memory device and can include allocating the cache entry to include allocating the cache entry in one or more static random-access memories in the controller dedicated to repair replacement.

In an example method 8 of operating a memory device, any of the example methods 1 to 7 of operating a memory device may be performed in operating an electronic apparatus further comprising a host processor and a communication bus extending between the host processor and the memory device.

In an example method 9 of operating a memory device, any of the example methods 1 to 8 of operating a memory device may be modified to include operations set forth in any other of example methods 1 to 8.

In an example method 10 of operating a memory device, any of the example methods 1 to 9 of operating a memory device may be implemented at least in part through use of instructions stored as a physical state in one or more machine-readable storage devices.

An example method 11 of operating a memory device can include features of any of the preceding example methods 1 to 10 of operating a memory device and can include performing functions associated with any features of example memory devices 1 to 12.

An example method 12 of operating a memory device can comprise in response to a repair trigger, allocating, in a controller of the memory device, a cache entry in a cache for a failing row, the failing row being in memory media of the memory device; and writing data of a last column related to the failing row to the cache, the data of the last column being data that triggered the repair.

An example method 13 of operating a memory device can include features of example method 12 of operating a memory device and can include inserting data of another column related to the failing row into the cache upon request from a host initiating the writing of the data.

An example method 14 of operating a memory device can include features of example method 13 of operating a memory device and any of the preceding example methods 12 to 13 of operating a memory device and can include, if the other column is not listed in the cache, inserting data of the other column in the cache from the memory media in a backend process.

An example method 15 of operating a memory device can include features of any of the preceding example methods 12 to 14 of operating a memory device and can include allocating the cache entry to include allocating the cache entry in a cache dedicated to repair replacement.

An example method 16 of operating a memory device can include features of example method 15 of operating a memory device and any of the preceding example methods 12 to 14 of operating a memory device and can include the cache being one or more static random-access memories in the controller.

In an example method 17 of operating a memory device, any of the example methods 12 to 16 of operating a memory device may be performed in operating an electronic apparatus further comprising a host processor and a communication bus extending between the host processor and the memory device.

In an example method 18 of operating a memory device, any of the example methods 12 to 17 of operating a memory device may be modified to include operations set forth in any other of example methods 12 to 17 of operating a memory device.

In an example method 19 of operating a memory device, any of the example methods 12 to 18 of operating a memory device may be implemented at least in part through use of instructions stored as a physical state in one or more machine-readable storage devices.

An example method 20 of operating a memory device can include features of any of the preceding example methods 12 to 19 of operating a memory device and can include performing functions associated with any features of example memory device 1 to 12.

An example method 21 of operating a memory device can include features of any of the preceding example methods 12 to 20 of operating a memory device and example methods 1 to 11 of operating a memory device and can include performing functions associated with any features of example memory device 1 to 12.

An example machine-readable storage device storing instructions, that when executed by one or more processors, cause a machine to perform operations, can comprise instructions to perform functions associated with any features of example memory devices 1 to 12 or perform methods associated with any features of example methods 1 to 11 of operating a memory device and example methods 12 to 21 of operating a memory device.

Although specific embodiments have been illustrated and described herein, it will be appreciated by those of ordinary skill in the art that any arrangement that is calculated to achieve the same purpose may be substituted for the specific embodiments shown. Various embodiments use permutations and/or combinations of embodiments described herein. It is to be understood that the above description is intended to be illustrative, and not restrictive, and that the phraseology or terminology employed herein is for the purpose of description.

What is claimed is:

1. A memory device comprising:
a memory subsystem; and
a controller coupled to the memory subsystem, the controller to control storage of user data, the controller having one or more caches, the one or more caches separate from the memory subsystem, the controller arranged to use the one or more caches to provide resource replacement to the memory subsystem.

2. The memory device of claim 1, wherein the memory subsystem has one or more memory media and the controller is configured to process user data with the one or more memory media sharing the one or more caches, the controller having an individual decoder/encoder for each memory medium of the one or more memory media, with the individual decoders/encoders configured between the one or more caches and the one or more memory media.

3. The memory device of claim 1, wherein the memory subsystem has multiple individual memory media, the controller has an individual decoder/encoder for each individual memory medium of the multiple individual memory media, the controller has multiple caches and is configured to process user data with each memory medium of the multiple individual memory media allocated to an individual cache of the multiple caches and with each individual decoder/encoder configured between a corresponding allocated cache and the individual memory medium corresponding to the individual decoder/encoder.

4. The memory device of claim 1, wherein the memory subsystem has one or more memory media and the controller is configured to process user data with the one or more memory media sharing the one or more caches, the controller having an individual decoder/encoder for each memory medium of the one or more memory media, with the one or more caches configured between the individual decoders/encoders and the one or more memory media.

5. The memory device of claim 1, wherein the memory subsystem has multiple individual memory media, and the controller includes:
an individual decoder and individual encoder for each individual memory medium of the multiple individual memory media; and
multiple caches, each cache of the multiple caches allocated to an individual memory medium of the multiple individual memory media, with each allocated cache configured between the individual memory medium and each individual decoder and individual encoder corresponding to the individual memory medium.

6. The memory device of claim 1, wherein the one or more caches include one or more static random-access memories.

7. The memory device of claim 1, wherein the controller is an application-specific integrated circuit.

8. The memory device of claim 1, wherein the controller is configured to repair one or more rows of the memory subsystem, based on a set of collected correctable error events, using the one or more caches.

9. A method of operating a memory device, the method comprising:
in response to a repair trigger, allocating, in a cache in a controller of the memory device, a cache entry for a failing row, the failing row being in memory media of the memory device; and
moving data related to the failing row to the cache in accordance with the allocated cache entry.

10. The method of claim 9, wherein read commands related to the failing row are put on hold until the moving of the data is completed.

11. The method of claim 9, wherein write commands related to the failing row are accepted and data is stored in the cache.

12. The method of claim 9, wherein the method includes responding to the repair trigger based on a set of collected correctable error events.

13. The method of claim 9, wherein moving data includes storing error correction code data in the cache.

14. The method of claim 9, wherein the method includes storing parity information in the cache.

15. The method of claim 9, wherein allocating the cache entry includes allocating the cache entry in one or more static random-access memories in the controller dedicated to repair replacement.

16. A method of operating a memory device, the method comprising:
in response to a repair trigger, allocating, in a cache in a controller of the memory device, a cache entry for a failing row, the failing row being in memory media of the memory device; and
writing data of a last column related to the failing row to the cache, the data of the last column being data that triggered the repair.

17. The method of claim 16, wherein the method includes inserting data of another column related to the failing row into the cache upon request from a host initiating the writing of the data.

18. The method of claim 17, wherein the method includes, if the other column is not listed in the cache, inserting data of the other column in the cache from the memory media in a backend process.

19. The method of claim 16, wherein allocating the cache entry includes allocating the cache entry in a cache dedicated to repair replacement.

20. The method of claim 19, wherein the cache is one or more static random-access memories in the controller.
